(19) United States
(12) Patent Application Publication
(10) Pub. No.: US 2008/0093592 A1
(43) Pub. Date: Apr. 24, 2008

(54) Phase-change memory and method of manufacturing the same

(75) Inventor: Hiroshi Moriya, Ushiku (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Renesas Technology Corp., Tokyo (JP)

(21) Appl. No.: 11/975,062

(22) Filed: Oct. 16, 2007

(30) Foreign Application Priority Data
Oct. 19, 2006 (JP) 2006-285084

(51) Int. Cl. H01L 47/00

(52) U.S. Cl. 257/4; 438/102; 257/E47.001; 257/E47.005

(57) ABSTRACT

A structure of a phase-change memory which enables low-current rewrite and a method of manufacturing the same are provided. The phase-change memory comprises: an interlayer insulating film and a plug formed over a main surface of a silicon substrate; a phase-change film formed over the plug; and an upper electrode film formed over the phase-change film. And the phase-change film and the insulating film are in contact with each other in an area formed by projecting an upper surface of the plug to a plane including a lower surface of the upper electrode film.

### CROSS-REFERENCE TO RELATED APPLICATION

The present application claims priority from Japanese Patent Application No. JP 2006-285084 filed on Oct. 19, 2006, the content of which is hereby incorporated by reference into this application.

### TECHNICAL FIELD OF THE INVENTION

The present invention relates to a technique for manufacturing a phase-change memory (phase-change type non-volatile memory). More particularly, the present invention relates to a technique effectively applied to a structure of a phase-change memory and a method of manufacturing the same.

### BACKGROUND OF THE INVENTION

In recent years, a phase-change type non-volatile memory (Phase-change Random Access Memory: PRAM) using phase-change chalcogenide material has been suggested as a next-generation non-volatile semiconductor memory. PRAM is predicted to be capable of high-speed writing/reading of memory at the same level as DRAM, while it is non-volatile. In addition, PRAM is capable of being integrated in a comparable cell area to flash memory. Therefore, PRAM is expected as the most promising next-generation non-volatile memory.

Chalcogenide materials to configure a phase-change film of PRAM have been already used for DVDs (Digital Versatile Discs). DVD utilizes a feature of chalcogenide that optical reflectance thereof is different between amorphous state and crystalline state. On the other hand, PRAM is an element which makes the phase-change material to operate as a memory by utilizing a feature that electrical resistance thereof has a difference of several orders of magnitude between amorphous state and crystalline state.

Switching of the phase-change memory, i.e., phase change of a phase-change material from amorphous state to crystalline state and vice versa is made by using Joule heat generated by applying a pulse voltage to the phase-change material. For the phase change of the phase-change material from amorphous state to crystalline state, a voltage to make the heat not lower than the crystallization temperature and not higher than the melting point is applied to the phase-change material. And, for the phase change from crystalline state to amorphous state, a short-pulse voltage to make the heat not lower than the melting point is applied to the phase-change material and the phase-change material is quenched.

Properties required to the phase-change memory include lower power consumption. To achieve this, a low-current rewrite structure, which makes a current required to change phase of the above phase-change material lower is required (e.g., Japanese Patent Application Laid-Open Publication No. 2006-120810 (Patent Document 1)). A low-current rewrite structure of a phase-change memory generally considered is a structure in which the area of plug for applying a current to the phase-change film is reduced. Further, for the reduction of the plug area, a structure where a surface of plug is formed in a donut shape is suggested and the structure is disclosed in, for example, “VLSI Technology, 2005. Digest of Technical Papers, pp. 98-99” (Non-patent Document 1).

### SUMMARY OF THE INVENTION

Meanwhile, in the technology of phase-change memory as described above, although it is possible to lower the rewriting current of the phase-change memory by reducing the plug area, as the reduction of the plug area is progressed, the processing becomes more difficult. Further, the processing is also difficult for the donut-shape plug described above. In other words, there is a problem that, a structure that achieves a further lower current cannot be obtained by just reducing the plug area.

Consequently, an object of the present invention is to provide a structure of a phase-change memory to enable low-current rewrite and a method of manufacturing the same.

The above and other objects and novel characteristics of the present invention will be apparent from the description of this specification and the accompanying drawings.

The typical ones of the inventions disclosed in this application will be briefly described as follows.

A phase-change memory of the present invention comprises: an interlayer insulating film and a plug formed on one main surface side of a semiconductor substrate; a phase-change film formed over the plug; and an electrode film formed over the phase-change film, and the phase-change film and an insulating film are in contact with each other in an area formed by projecting an upper surface of the plug to a plane including a lower surface of the electrode film.

And, a method of manufacturing a phase-change memory of the present invention includes the steps of: forming an interlayer insulating film and a plug on one main surface side of a semiconductor substrate; forming a phase-change film over the plug; forming an electrode film over the phase-change film; etching the insulating film in an area formed by projecting an upper surface of the plug to a plane including a lower surface of the electrode film until the phase-change film is exposed; and forming an insulating film over the electrode film.

The effects obtained by typical aspects of the present invention will be briefly described below.

According to the present invention, the phase-change film and the insulating film are in contact with each other in the area formed by projecting the upper surface of the plug to the plane including the lower surface of the electrode film, so that an excess temperature rising at the center of a cell can be suppressed and a phase distribution of crystalline/amorphous phases achieving an effective change of resistance can be obtained. Therefore, low-current rewrite of a phase-change memory can be achieved.

### BRIEF DESCRIPTIONS OF THE DRAWINGS

FIG. 1 is a cross-sectional diagram showing a main part of a phase-change memory according to a first embodiment of the present invention;

FIG. 2 is a circuit diagram showing a memory cell array of the phase-change memory according to the first embodiment of the present invention;

FIG. 3 is an enlarged cross-sectional diagram showing a vicinity of a phase-change film shown in FIG. 1 of the phase-change memory according to the first embodiment of the present invention;

FIG. 4 is a cross-sectional diagram showing a plane cut along the cutting line A-A′ shown in FIG. 3 of the phase-change memory according to the first embodiment of the present invention;

FIG. 5 is a diagram showing a relationship between a diameter of a hole of an upper electrode film and a current required for reset rewrite (thickness of phase-change film: 50 nm) of the phase-change memory according to the first embodiment of the present invention;

FIG. 6 is a diagram showing a relationship between a diameter of the hole of the upper electrode film and a current required for reset rewrite (thickness of phase-change film: 30 nm) of the phase-change memory according to the first embodiment of the present invention;

FIG. 7A is a diagram showing a temperature distribution of the phase-change film of the phase-change memory according to the first embodiment of the present invention, in a case where the hole does not exist in the upper electrode film;

FIG. 7B is a diagram showing a temperature distribution of the phase-change film of the phase-change memory according to the first embodiment of the present invention, in a case where the hole exists in the upper electrode film;

FIG. 8A is a diagram showing a temperature distribution in a vicinity of an interface of a plug and an interlayer insulating film of the phase-change film of the phase-change memory according to the first embodiment of the present invention, in a case where the hole does not exist in the upper electrode film and a case where the hole exists in the upper electrode film;

FIG. 8B is a diagram showing a structure of a conventional phase-change memory in which the hole does not exist in the upper electrode film;

FIG. 8C is a diagram showing a structure of a phase-change memory according to the first embodiment of the present invention in which the hole exists in the upper electrode film;

FIG. 9A is a diagram showing a phase distribution after rewrite of the phase-change film of the phase-change memory according to the first embodiment of the present invention, in a case where the hole does not exist in the upper electrode film;

FIG. 9B is a diagram showing a phase distribution after rewrite of the phase-change film of the phase-change memory according to the first embodiment of the present invention, in a case where the hole exists in the upper electrode film;

FIG. 10 is a cross-sectional diagram showing a method of manufacturing a main part of the phase-change memory according to the first embodiment of the present invention;

FIG. 11 is a cross-sectional diagram showing the method of manufacturing the main part of the phase-change memory according to the first embodiment of the present invention continued from FIG. 10;

FIG. 12 is a cross-sectional diagram showing the method of manufacturing the main part of the phase-change memory according to the first embodiment of the present invention continued from FIG. 11;

FIG. 13 is a cross-sectional diagram showing the method of manufacturing the main part of the phase-change memory according to the first embodiment of the present invention continued from FIG. 12;

FIG. 14 is a cross-sectional diagram showing the method of manufacturing the main part of the phase-change memory according to the first embodiment of the present invention continued from FIG. 13;

FIG. 15 is a cross-sectional diagram showing the method of manufacturing the main part of the phase-change memory according to the first embodiment of the present invention continued from FIG. 14;

FIG. 16 is a cross-sectional diagram showing the method of manufacturing the main part of the phase-change memory according to the first embodiment of the present invention continued from FIG. 15;

FIG. 17 is a cross-sectional diagram showing the method of manufacturing the main part of the phase-change memory according to the first embodiment of the present invention continued from FIG. 16;

FIG. 18 is a diagram showing an operation principle (operation pulse) of the phase-change memory according to the first embodiment of the present invention;

FIG. 19 is a diagram showing an operation principle (temperature history) of the phase-change memory according to the first embodiment of the present invention;

FIG. 20 is a cross-sectional diagram showing a method of manufacturing a main part of a phase-change memory according to a second embodiment of the present invention;

FIG. 21 is a cross-sectional diagram showing the method of manufacturing the main part of the phase-change memory according to the second embodiment of the present invention continued from FIG. 20;

FIG. 22 is a cross-sectional diagram showing the method of manufacturing the main part of the phase-change memory according to the second embodiment of the present invention continued from FIG. 21;

FIG. 23 is a cross-sectional diagram showing the method of manufacturing the main part of the phase-change memory according to the second embodiment of the present invention continued from FIG. 22;

FIG. 24 is a cross-sectional diagram showing a main part of a phase-change memory according to a third embodiment of the present invention;

FIG. 25 is an enlarged cross-sectional diagram showing a vicinity of a phase-change film shown in FIG. 24 of the phase-change memory according to the third embodiment of the present invention;

FIG. 26 is a cross-sectional diagram showing a plane cut along the cutting line A-A′ shown in FIG. 25 of the phase-change memory according to the third embodiment of the present invention;

FIG. 27 is a cross-sectional diagram showing a method of manufacturing a main part of the phase-change memory according to the third embodiment of the present invention;

FIG. 28 is a cross-sectional diagram showing the method of manufacturing the main part of the phase-change memory according to the third embodiment of the present invention continued from FIG. 27; and

FIG. 29 is a cross-sectional diagram showing the method of manufacturing the main part of the phase-change memory according to the third embodiment of the present invention continued from FIG. 28.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

### First Embodiment

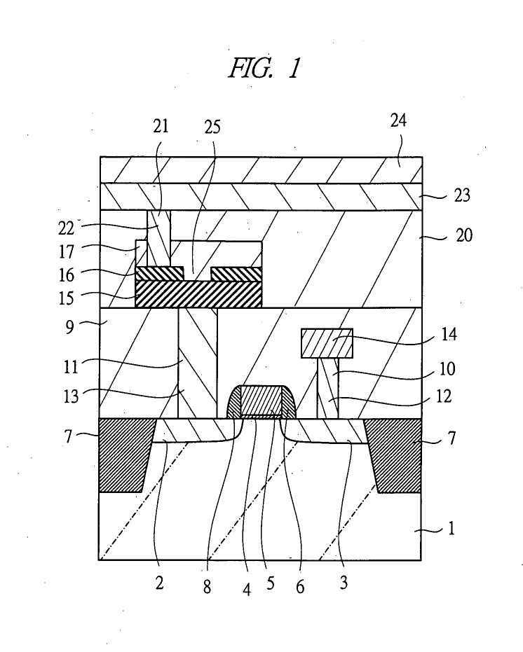

A first embodiment of the present invention will be described with reference to FIG. 1 to FIG. 19.

First, FIG. 1 is a cross section structure of a main part of a phase-change memory according to the first embodiment of the present invention. As shown in FIG. 1, the phase-change memory of the present embodiment includes diffusion layers 2, 3 formed over a silicon substrate 1, and a gate insulating film 4 and a gate electrode 5 formed thereon so that a MOS (Metal Oxide Semiconductor) transistor 6 is structured. The gate insulating film 4 is formed of, for example, a silicon oxide film or a silicon nitride film, and the gate electrode 5 is formed of, for example, a polycrystalline silicon film, a metal thin film, or a metal silicide film, and alternatively, a multilayered structure of these films. The MOS transistor 6 is isolated by an isolation film 7 formed of, for example, a silicon oxide film.

An insulating film 8 formed of, e.g., a silicon oxide film is formed over sidewalls of the gate electrode 5. A first interlayer insulating film 9 formed of, e.g., a BPSG (Boron-Doped Phospho-Silicate Glass) film, a SOG (Spin On Glass) film, or a silicon oxide film, a silicon nitride film and the like formed by CVD or sputtering is formed over the whole surface of an upper side of the MOS transistor 6.

Contact holes 10, 11 are formed in the first interlayer insulating film 9. Plugs 12, 13 formed of an conductive member covered by an adjacent conductive film of, e.g., titanium nitride (TiN) for preventing diffusion are formed and connected to the diffusion layers 2, 3, respectively. In addition, the plug 12 is connected to a wiring 14 connected to the ground.

A phase-change film 15 including, e.g., germanium-antimony-tellurium (Ge₂Sb₂Te₅) as a main component, an upper electrode film 16 formed of tungsten (W), and an insulating film 17 formed of a silicon oxide (SiO₂) film are formed over a surface of the plug 13 and a part of a surface of the first interlayer insulating film 9.

A second interlayer insulating film 20 is formed over the surface of the first interlayer insulating film 9 and a surface of the multilayered member of the phase-change film 15, the upper electrode film 16, and the insulating film 17. A contact hole 21 is formed in the second interlayer insulating film 20. A plug 22 formed of a conductive member covered by an adjacent conductive film of, e.g., titanium nitride (TiN) for preventing diffusion is formed and connected to the upper electrode film 16. Further, a wiring 23 electrically connected to the plug 22 is formed over a surface of the second interlayer insulating film 20. A third interlayer insulating film 24 is further formed over the wiring 23.

Here, a hole 25 is formed in the upper electrode film 16 above the plug 13. Accordingly, a vertical flow of current from the plug 13 to an electrode of the upper electrode film 16 or a vertical flow of current from the electrode to the plug 13 is blocked. Although the hole 25 is filled with the insulating film 17 in FIG. 1, it is not necessarily filled. Meanwhile, when the hole 25 is filled with the insulating film 17, flowability of the phase-change film 15 in writing can be suppressed, thus the phase-change film 15 gets stabilized. A storage part of the phase-change memory is structured as the structure described above.

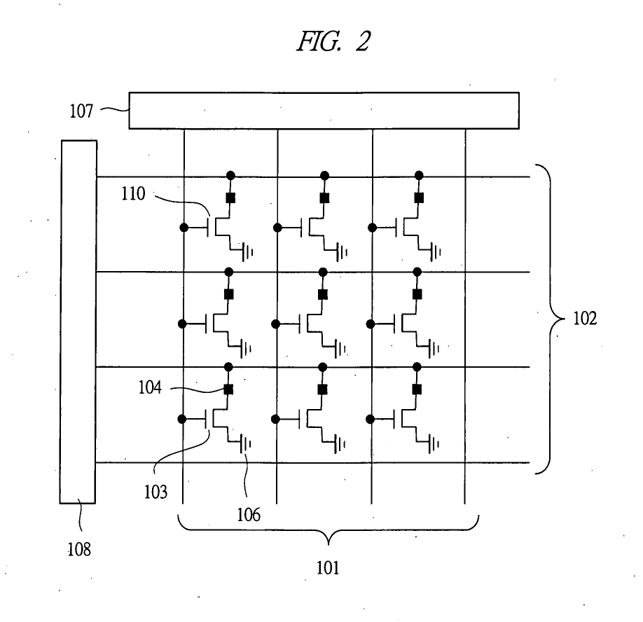

FIG. 2 is a circuit diagram of a memory cell array of the phase-change memory of the present embodiment. In the memory cell array of the phase-change memory of the present embodiment, a plurality of word lines 101 and a plurality of bit lines 102 are wired in a matrix arrangement, and memory cells 110 are connected thereto respectively. The memory cell 110 includes a transistor 103 and a phase-change film 104 and is connected to a ground 106. Further, driver circuits 107, 108 connected to the word line 101 and the bit line 102 are arranged. The driver circuits 107, 108 select any of the memory cells 110 so that reading and writing of information is performed.

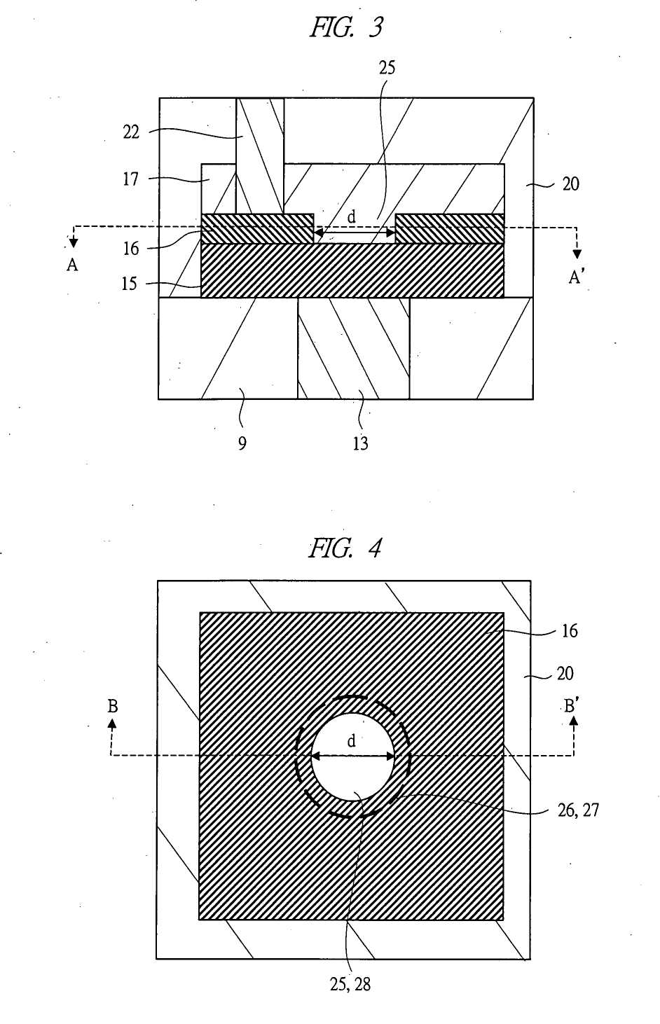

FIG. 3 is an enlarged diagram of FIG. 1 showing a vicinity of the phase-change film, which is a cross-sectional diagram cut along the cutting line B-B′ shown in a plan diagram of FIG. 4 as well. FIG. 4 is a cross-sectional diagram showing a plane cut along the cutting line A-A′ dividing the electrode of FIG. 3 in a thickness direction. Herein, as shown in FIG. 4, the hole 25 is formed in the upper electrode film 16 and filled with the insulating film 17. In addition, an area 27 surrounded by an outer circumference 26 of the plug 13 and an area 28 surrounded by an outer circumference of the hole 25 are arranged so as to overlap each other at least in a part.

Accordingly, when a current flows from the plug 13 to the upper electrode film 16 through the phase-change film 15, a current flowing from a vicinity of the center of the plug 13 to a vicinity of the center of the electrode is blocked. Alternatively, when current flows from a vicinity of the electrode to the plug 13 through the phase-change film 15, a current flowing from the center of the electrode to the center of the plug 13 is blocked. Herein, the vicinity of the center of the electrode means a vicinity of a point where a perpendicular drawn from the center of the plug 13 toward the electrode crosses a plane forming the electrode. According to the hole 25 formed in the electrode as described above, less current is required to rewrite compared with a structure without the hole 25. In other words, a phase-change memory capable of rewrite with low current can be obtained.

Next, this low-current rewrite will be described. FIG. 5 shows a relationship between a diameter of the hole 25 formed in the upper electrode film 16 in FIG. 4 and a current required for reset-rewriting. Herein, reset-rewrite means a rewrite operation to make the phase-change film 15 in crystalline state of low resistance to be amorphous state of high resistance by heating it over its melting point with Joule heat and then quenching. This rewrite operation requires the largest current in rewrite operations of a phase-change memory. In addition, FIG. 5 shows a case with a diameter of the plug of 180 nm and a thickness of the phase-change film of 50 nm. It is a result of a simulation where a bit-line voltage as a voltage value of the upper electrode is 1.5 V and a word voltage as a gate voltage of the transistor is changed from 1.0 V to 1.5 V.

The legend symbol • indicates success of reset-rewrite and that of x indicates failure of reset-rewrite. The criterion of judging success and failure is the change in resistance. When an over 1000-fold of resistance change is obtained by rewrite, the legend symbol • is plotted, and it is not obtained, the legend symbol x is plotted. As shown in FIG. 5, when the hole is not formed in the upper electrode film (d=0), a current required for reset-rewrite is about 125 μA. On the contrary, when a hole having a diameter of, e.g., d=160 nm is formed, the current required for reset-rewrite is decreased to about 112 μA. In other words, a lower current decreased by about 10% is achieved by forming a hole.

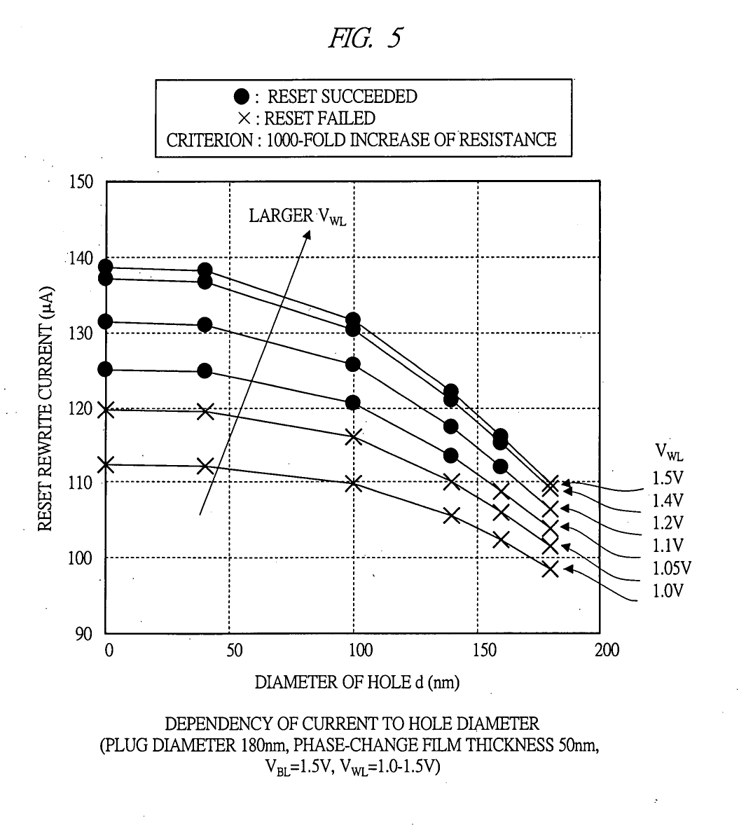

Similarly, FIG. 6 shows a case with a diameter of the plug of 180 nm and a thickness of the phase-change film of 30 nm. It is a result of a simulation where the bit-line voltage as the voltage value of the upper electrode is 1.5 V and the word voltage as the gate voltage of the transistor is changed from 1.0 V to 1.5 V. The legend symbols indicate the same as those in FIG. 5. With the thickness of the phase-change film of 30 nm, when the hole is not formed in the upper electrode film (d=0), the current required for reset-rewrite is about 135 μA. On the contrary, when a hole having a diameter of, e.g., 180 nm is formed in the upper electrode film, the current required for reset-rewrite is decreased to about 102 μA. In other words, a lower current decreased by over 20% is achieved by forming a hole.

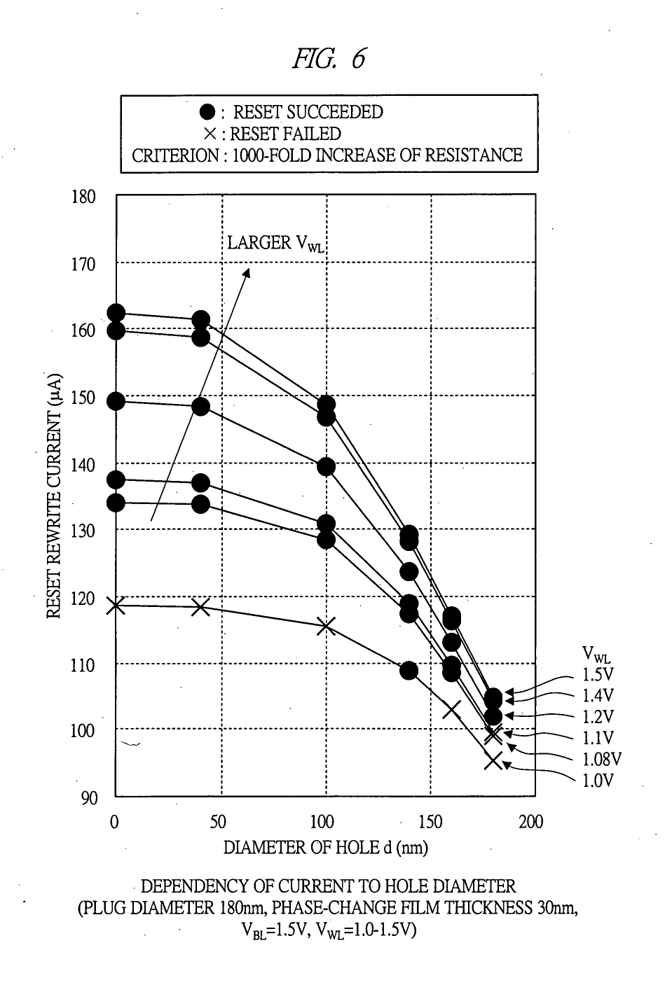

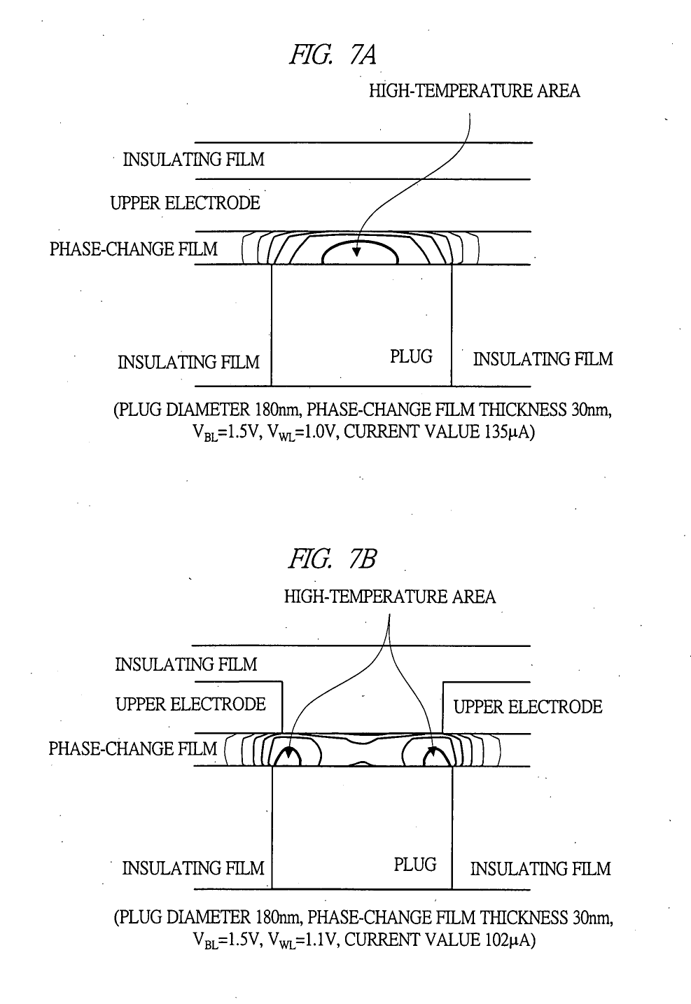

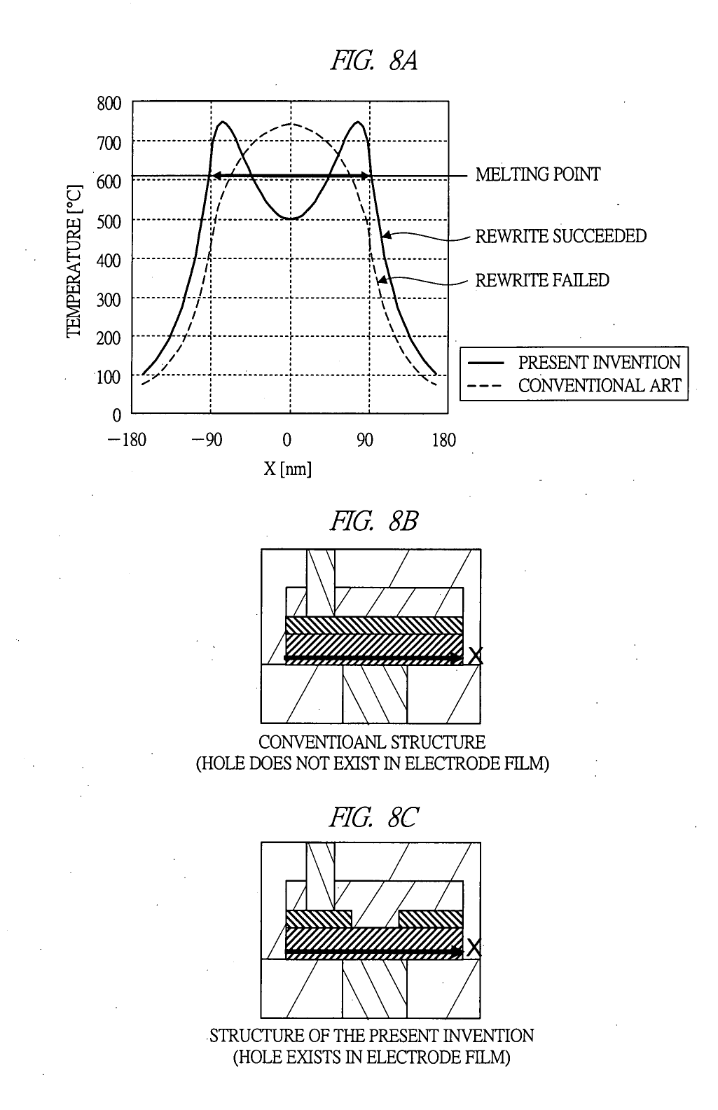

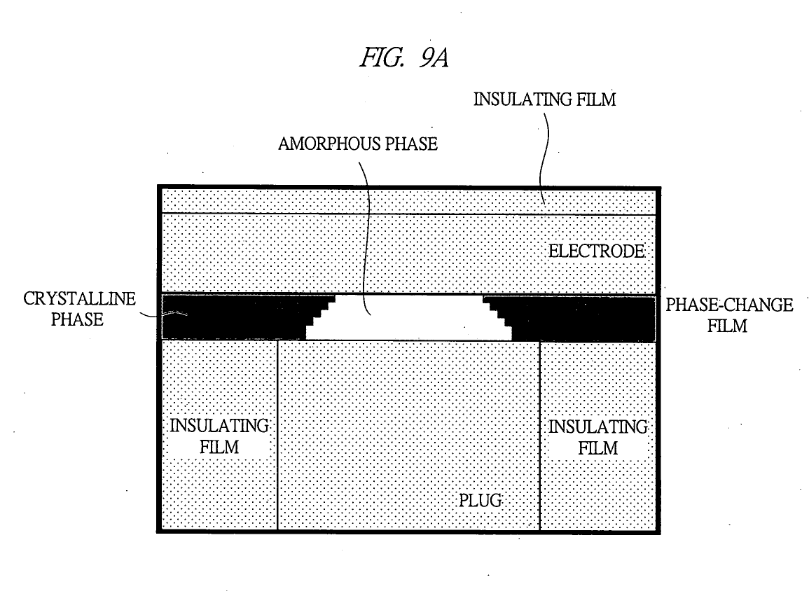

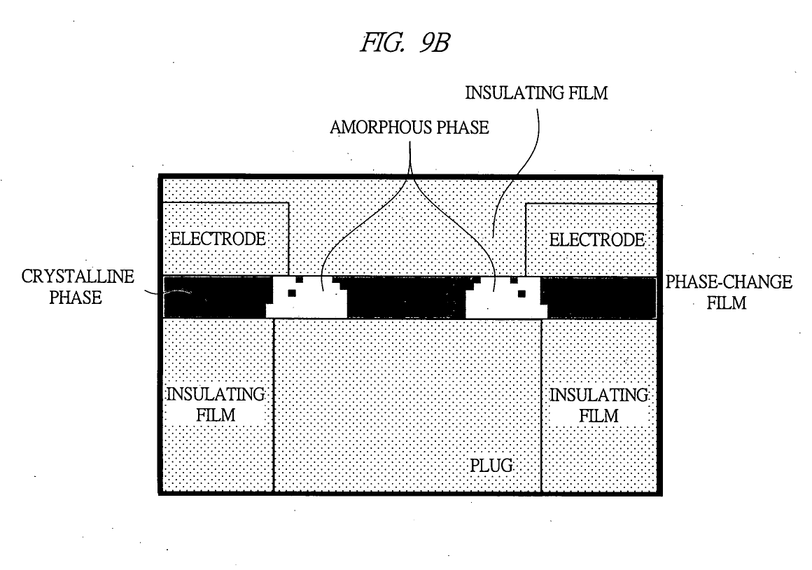

Next, with reference to FIGS. 7A and 7B to FIGS. 9A and 9B, a mechanism of achieving lower-current by the hole in the upper electrode film will be described. FIGS. 7A and 7B show temperature distributions of the phase-change film at rewrite, in which FIG. 7A shows a case of the upper electrode film without a hole and FIG. 7B shows a case of the upper electrode film with a hole. FIG. 8A shows temperature distributions in a vicinity of an interface of the plug and the interlayer insulating film of the phase-change film without a hole in the upper electrode (a conventional structure shown in FIG. 8B) and that with a hole in the upper electrode (the structure of the present invention shown in FIG. 8C). FIGS. 9A and 9B show phase distributions of the phase-change film after rewrite (FIG. 9A shows a case with a conventional structure and FIG. 9B shows a case with the structure of the present invention).

By forming a hole in the upper electrode film as shown in FIG. 7B and FIG. 8C, the area of high temperature shifts from the vicinity of the center of the phase-change film to the vicinity of the periphery of the plug. The reason of this shift is that the hole in the upper electrode film blocks a current flowing directly from the vicinity of the center of the electrode (or the vicinity of the center of the plug) to the vicinity of the center of the plug (or the vicinity of the center of the electrode) and accordingly the Joule heat in the vicinity of the center is lowered, and the temperature rising is thus suppressed to be low.

In accordance with these temperature distributions, phase distributions after rewrite become a state shown in FIGS. 9A and 9B. When the hole in the upper electrode film does not exist (FIG. 9A), the phase-change film near the center on the plug becomes amorphous by being heated over its melting point. However, although a current of about 135 μA is applied, the phase-change film is not fully amorphous in the periphery of the plug. Therefore, rewrite is not succeeded. On the other hand, when the hole exists in the upper electrode film (FIG. 9B), the temperature in the periphery of the plug is raised intensively, so that it is completed to make the phase-change film in the periphery of the plug amorphous. In addition, the temperature of the phase-change film is not heated to the melting point at the vicinity of the center of the plug and so the phase-change film thereof remains crystalline but the crystalline phase of the center is surrounded by the high-resistance amorphous and the insulating film. Therefore, a read current does not flow through the aforementioned crystalline phase which has not become amorphous so that a high resistance value as a memory cell is obtained. More specifically, a lower current is obtained by forming the hole in the electrode because the temperature distribution which is capable of an efficient change of resistance ratio before and after rewrite is obtained.

In this manner, according to the present embodiment, an excess temperature rising at the center of the memory cell is suppressed, and a phase distribution of crystalline/amorphous phases which is capable of an efficient change of resistance can be obtained. As a result, low-current rewrite of a phase-change memory can be realized.

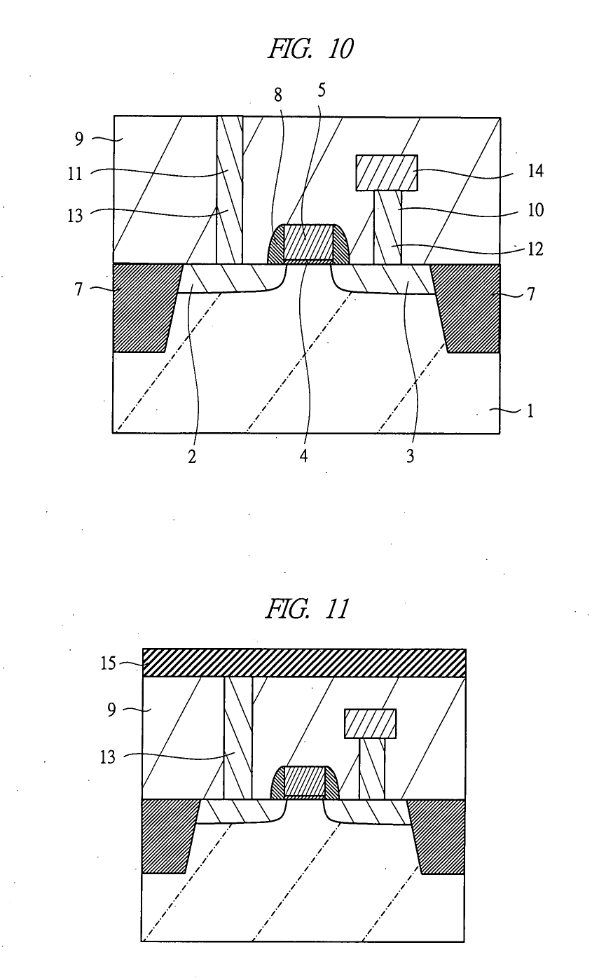

Next, a method of manufacturing a main part of the phase-change memory of the present embodiment will be described with reference to FIG. 10 to FIG. 17.

First, as shown in FIG. 10, in the phase-change memory of the present embodiment, by a method similar to the conventional one, diffusion layers 2, 3 are formed over the silicon substrate 1, and the gate insulating film 4 and the gate electrode 5 are formed thereon, so that a MOS transistor is structured. The gate insulating film 4 is formed of, for example, a silicon oxide film, and the gate electrode 5 is formed of, for example, a polycrystalline silicon film, a metal thin film, or a metal silicide film, and alternatively, a multilayered structure of these films. The MOS transistor is isolated by the isolation film 7 formed of, for example, a silicon oxide film.

The insulating film 8 formed of, e.g., a silicon oxide (SiO₂) film is formed over sidewalls of the gate electrode 5. The first interlayer insulating film 9 formed of, e.g., a BPSG film, a SOG film, or else, a silicon oxide film, silicon nitride film and the like formed by CVD or sputtering is formed over the whole surface of the upper side of the MOS transistor.

Contact holes 10, 11 are formed in the first interlayer insulating film 9. Plug 12 formed of a conductive member covered by an adjacent conductive film of, e.g., titanium oxide for preventing diffusion and plug 13 formed of a conductive member covered by an adjacent conductive film are formed and connected to the diffusion layers 2, 3, respectively. The plug 12 is connected to the wiring 14. Here, surfaces of the first interlayer insulating film 9 and the plug 13 are planarized through CMP (Chemical Mechanical Polishing) and the like (FIG. 10).

Then, as shown in FIG. 11, the phase-change film 15 formed of, e.g., germanium-antimony-tellurium (Ge₂Sb₂Te₅) is formed over surfaces of the first interlayer insulating film 9 and the plug 13 by, e.g. sputtering. Further, as shown in FIG. 12, over a surface of the phase-change film 15, the upper electrode film 16 of tungsten (W) is formed by, e.g., sputtering, and the insulating film 17 formed of a silicon oxide (SiO₂) film is formed by CVD.

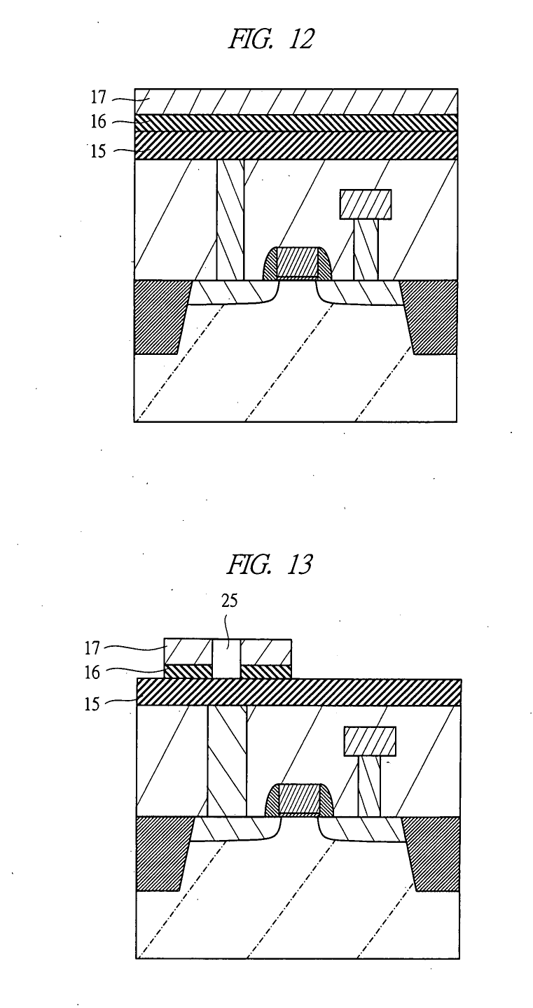

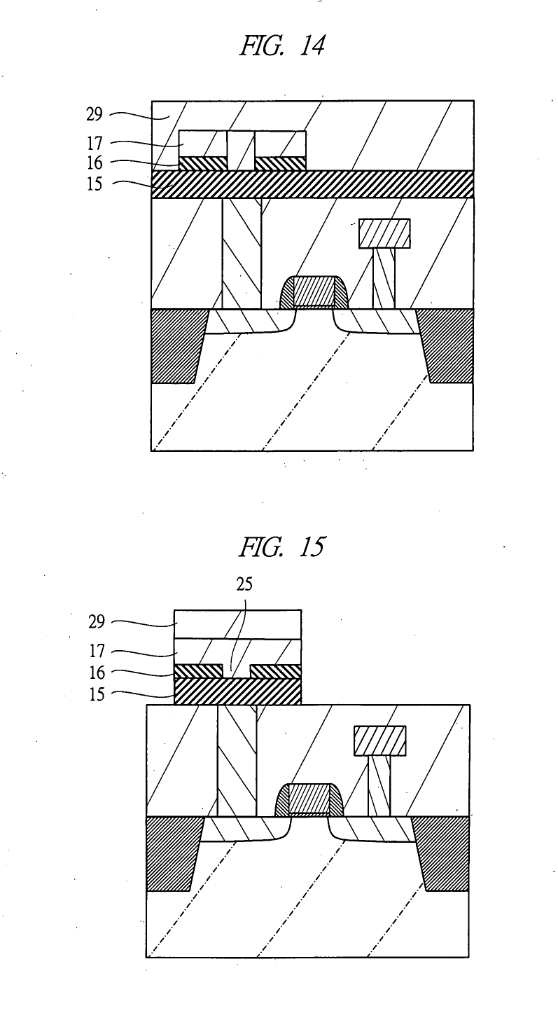

Next, as shown in FIG. 13, the insulating film 17 and the upper electrode film 16 are patterned through dry etching. At this time, a vicinity of the center of the upper electrode film 16 over the plug 13 is also etched so that the hole 25 is formed. And, as shown in FIG. 14, an interlayer insulating film 29 is formed by CVD. At the same time, the hole 25 is filled with an insulating film. A surface of the interlayer insulating film 29 is planarized through CVD and the like. Further, as shown in FIG. 15, the interlayer insulating film 29 and the phase-change film 15 are patterned so that a writing part of the memory is formed.

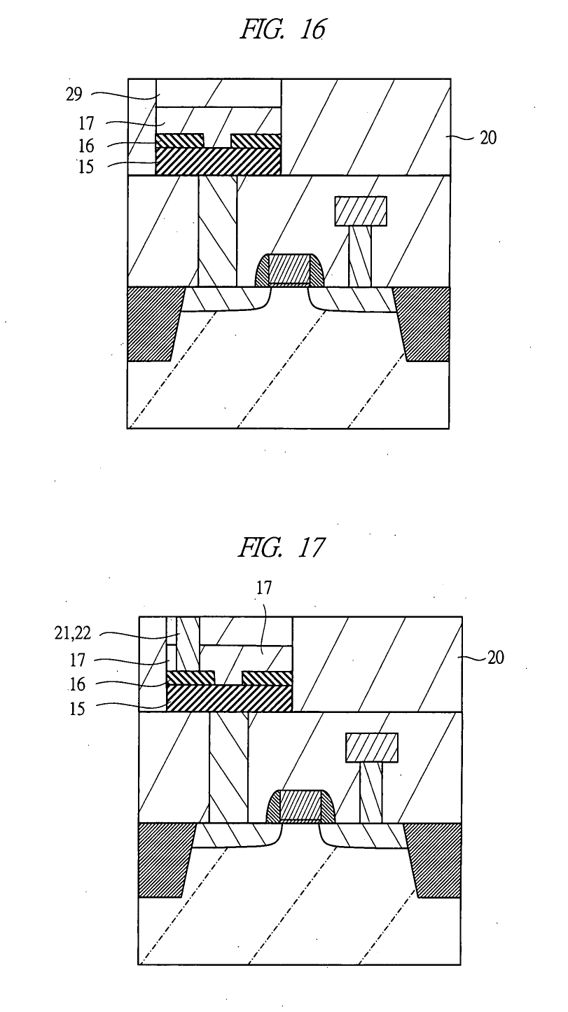

Subsequently, as shown in FIG. 16, the second interlayer insulating film 20 is formed and a surface thereof is planarized through CMP and the like. Etching on a part of the interlayer insulating film 29 and the insulating film 17 is followed to form the contact hole 21, and the plug 22 formed of, e.g., tungsten is formed by sputtering and the like. This plug 22 is electrically connected to the upper electrode film 16. Surfaces of the second interlayer insulating film 20 and the plug 22 are planarized through CMP and the like (FIG. 17).

Then, the wiring 23 formed of aluminum is formed by, for example, sputtering over the surfaces of the second interlayer insulating film 20 and the plug 22. And the third interlayer insulating film 24 is further formed by CVD, thereby forming the main part of the memory cell of the phase-change memory of FIG. 1 described above. Note that, the interlayer insulating film 29 is described being combined with the interlayer insulating film 20 in FIG. 1.

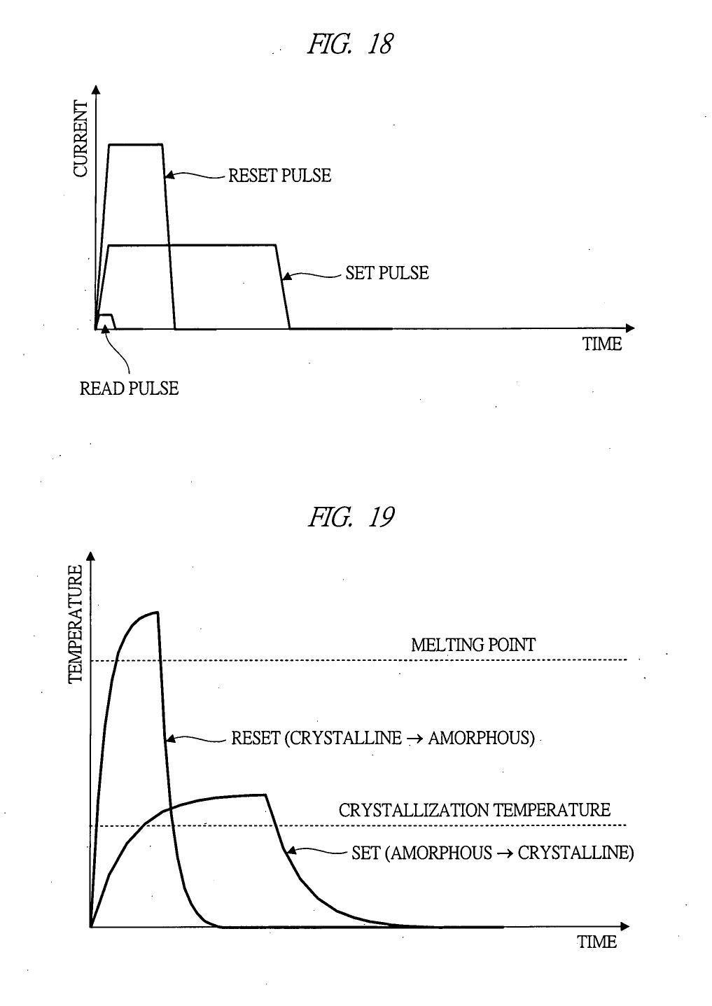

Next, an operation principle of the phase-change memory of the present embodiment is described with reference to FIG. 18 and FIG. 19. A phase-change memory is a device where the phase-change material utilized in DVD recording media is applied to a semiconductor memory. Recording information to the DVD recording media is performed by changing the state of phase-change material into amorphous or crystalline by a laser pulse and utilizing the difference in refractive index between the amorphous state and the crystalline state. On the other hand, for PRAM, a pulse voltage is applied to the memory cell and the state of amorphous or crystalline is selected by adjusting the voltage and pulse period. At this time, the electrical resistance is different between the amorphous state and the crystalline state by over about 1000-fold, and so information is recorded utilizing the difference in electrical resistance.

As shown in FIG. 18, a short-period pulse of a comparatively large current (reset pulse) is applied in the switching (reset) of the memory cell from the crystalline state to the amorphous state. A long-period pulse of a comparatively small current (set pulse) is applied in the switching (set) from the amorphous state to the crystalline state. Moreover, in reading, a short-period pulse of a small current (read pulse) is applied to the memory cell to read information of the memory according to the resistance value of the memory cell.

As shown in FIG. 19, by the reset pulse, the memory cell is melted by the large current flowing and the memory cell is changed from the crystalline state to the amorphous state because cooling is rapidly done because the pulse width is short. On the other hand, by the set pulse, the memory cell is changed from the amorphous state to the crystalline state by applying a current which makes the temperature of the memory cell exceeds a certain level of the crystallization temperature.

As described above, according to the phase-change memory of the present embodiment, it is possible to suppress an excess temperature rising at the center of the cell and obtain a phase distribution of crystalline/amorphous phases which is capable of an effective resistance change by means of a structure in which the phase-change film 15 and the insulating film 17 are in contact with each other in an area formed by projecting an upper surface of the plug 13 onto a plane including a lower surface of the upper electrode film 16. In other words, by means of a structure having the insulating film 17 over an upper surface of the phase-change film 15 formed by projecting the surface of the plug 13 toward the upper electrode film 16. As a result, low-current rewrite of the phase-change memory can be achieved.

### Second Embodiment

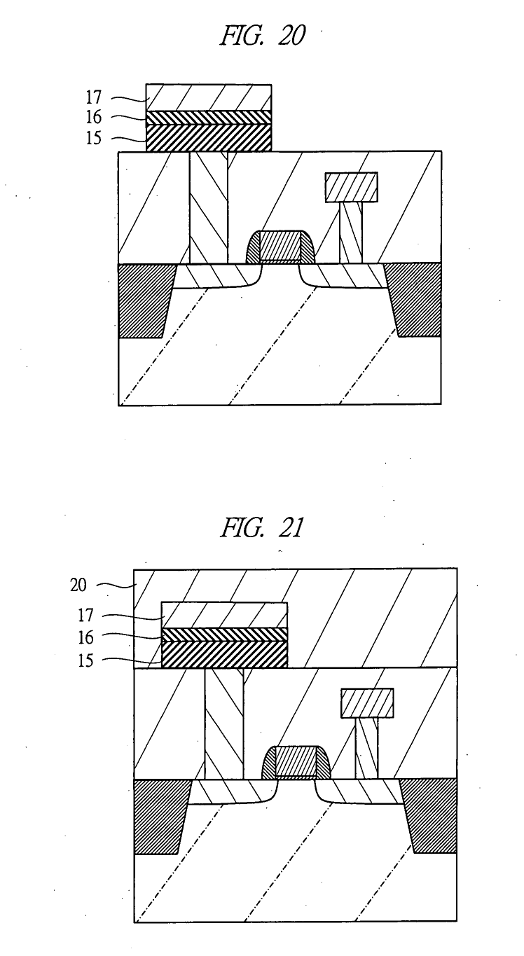

A second embodiment of the present invention will be described with reference to FIG. 20 to FIG. 23.

As the second embodiment of the present invention, the other method of manufacturing the main part of the phase-change memory shown in FIG. 1 described above is described using FIG. 20 to FIG. 23.

The method of manufacturing the phase-change memory of the present invention is implemented similarly as the method of manufacturing of the first embodiment until the step of FIG. 12.

Next, as shown in FIG. 20, the insulating film 17, the upper electrode film 16, and the phase-change film 15 are patterned through dry etching. Then, as shown in FIG. 21, the interlayer insulating film 20 is formed by CVD.

Subsequently, as shown in FIG. 22, the second interlayer insulating film 20, the insulating film 17, and the upper electrode film 16 over the plug 13 are etched so that the hole 25 is formed. The hole 25 is filled with an insulating film subsequently by CVD. Further, the surface of the second interlayer insulating film 20 is planarized through CMP and the like.

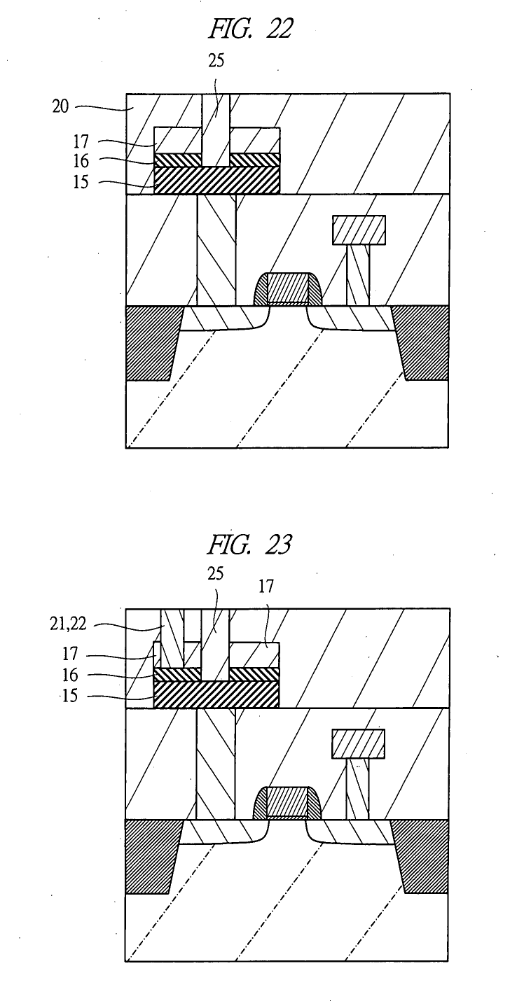

Next, as shown in FIG. 23, a part of the second interlayer insulating film 20 and the insulating film 17 is etched to form the contact hole 21, and the plug 22 formed of, e.g., tungsten is formed through spattering. This plug 22 is electrically connected to the upper electrode film 16. Surfaces of the second interlayer insulating film 20 and the plug 22 are planarized through CMP and the like.

Then, the wiring 23 formed of aluminum is formed through, for example, spattering over the surfaces of the second interlayer insulating film 20 and the plug 22. And the third interlayer insulating film 24 is further formed by CVD so that the main part of the memory cell of the phase-change memory shown in FIG. 1 is formed.

Also in the phase-change memory of the present embodiment, similarly to the first embodiment described above, en excess temperature rising at the center of the cell is suppressed and a phase distribution of crystalline/amorphous phases which is capable of an efficient resistance change can be obtained. As a result, low-current rewrite of the phase-change memory can be achieved.

### Third Embodiment

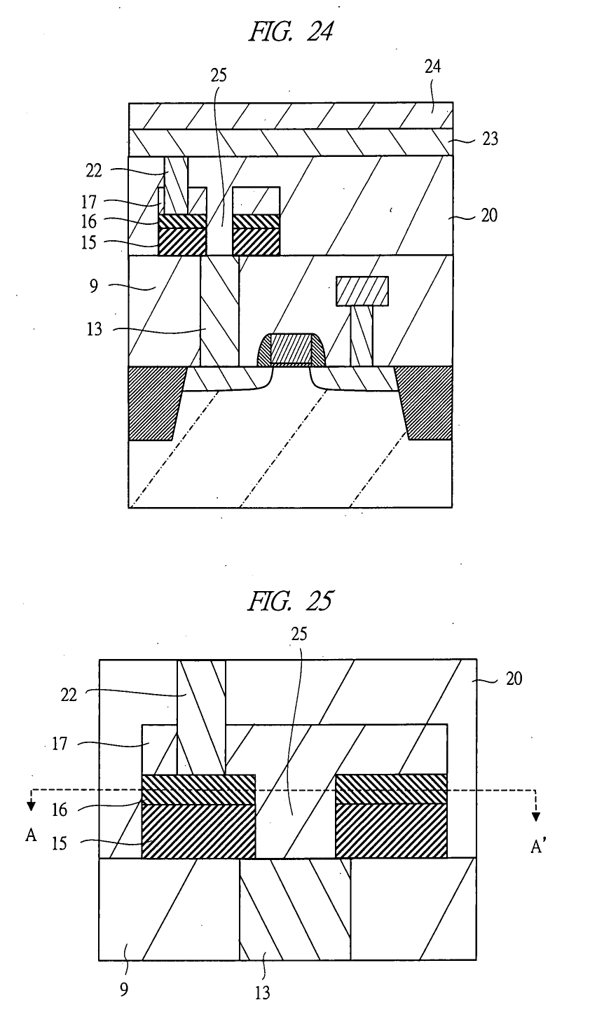

A third embodiment of the present invention will be described with reference to FIG. 24 to FIG. 29.

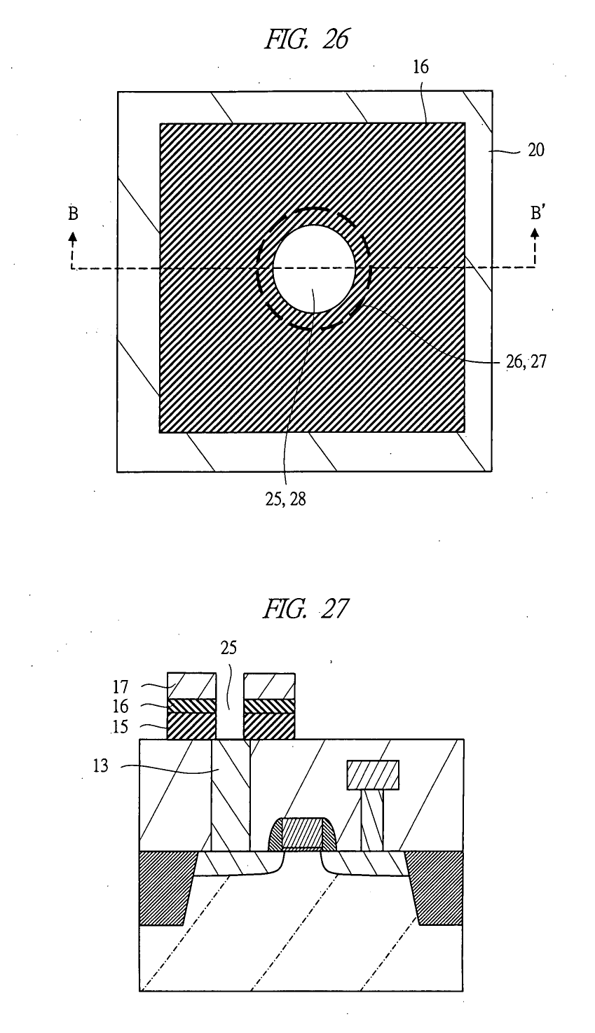

As the third embodiment of the present invention, the other structure of phase-change memory which achieves low-current rewrite is described with reference to FIG. 24 to FIG. 26. FIG. 24 is a cross-sectional diagram of a main part of the phase-change memory of the present embodiment. FIG. 25 is an enlarged diagram of a vicinity of a phase-change film of FIG. 24, as well as a cross-sectional diagram cut along the cutting line B-B′ shown in FIG. 26. And, FIG. 26 is a cross-sectional diagram cut along the cutting line A-A′ shown in FIG. 25.

A difference between the present embodiment and the phase-change memory shown in FIG. 1 lies in that the hole formed in the upper electrode film of FIG. 1 penetrates the phase-change film so as to reach a surface of the plug. Note that, in order to have an electrical continuity among the upper electrode film 16, the phase-change film 15, and the plug 13, the diameter of the hole 25 described above is smaller than that of the surface of the plug 13. In the structure described above, a current flows from the electrode to only near the plug through the phase-change film, or a current flows only from near the plug to the electrode though the phase-change film. Therefore, a wasteful current does not flow through the phase-change film and so rewrite of the phase-change film is sufficiently performed. As a result, low-current rewrite can be achieved.

Next, a method of manufacturing a main part of the phase-change memory of the present embodiment will be described with reference to FIG. 27 to FIG. 29.

The method of manufacturing a phase-change memory of the present embodiment is implemented similarly as the method of manufacturing according to the first embodiment described above until the step of FIG. 12.

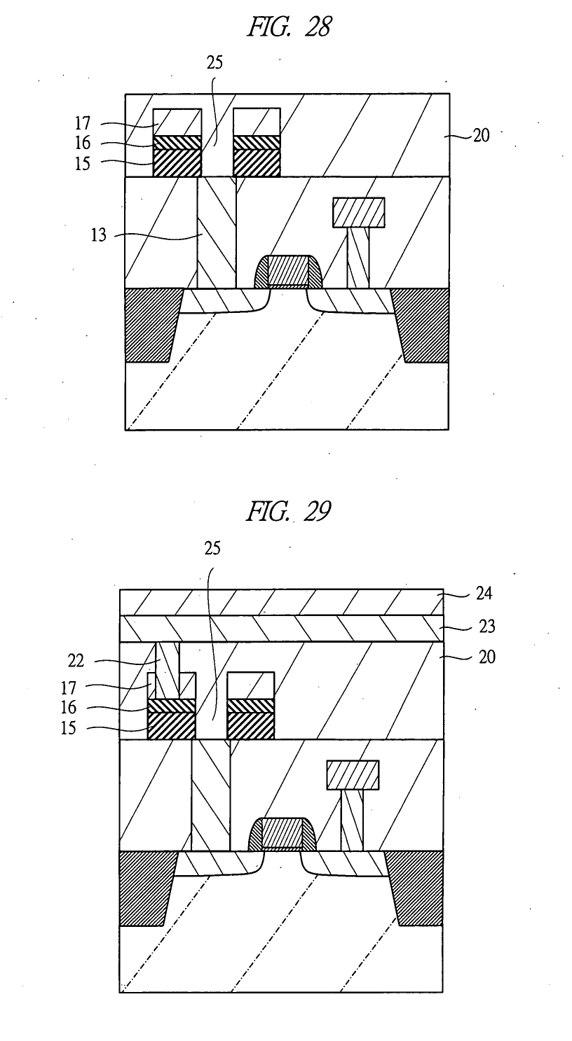

Subsequently, as shown in FIG. 27, the insulating film 17, the upper electrode film 16, and the phase-change film 15 are patterned through dry etching. Here, at the same time, the hole 25 is formed in the upper electrode film 16 and the phase-change film 15, so that the hole 25 penetrates so as to reach a surface of the plug 13. Then, as shown in FIG. 28, the second interlayer insulating film 20 is formed by CVD. Further, at the same time, the hole 25 formed earlier is filled with an insulating film. In addition, a surface of the second interlayer insulating film 20 is planarized through CMP and the like.

Next, as shown in FIG. 29, a contact hole is formed by etching a part of the second interlayer insulating film 20 and the insulating film 17, and the plug formed of, for example, tungsten is formed by sputtering. This plug 22 is electrically connected to the upper electrode film 16. Surfaces of the second interlayer insulating film 20 and the plug 22 are planarized through CMP and the like.

Then, the wiring 23 formed of aluminum is formed through, for example, sputtering over surfaces of the second interlayer insulating film 20 and the plug 22. And the third interlayer insulating film 24 is formed through CVD, thereby forming the main part of the memory cell of the phase-change memory shown in FIG. 24.

Also in the phase-change memory of the present embodiment, similarly as the first embodiment described above, an excess temperature rising at the center of the cell is suppressed, and a phase distribution of crystalline/amorphous phases which is capable of an efficient resistance change can be obtained. As a result, low-current rewrite can be achieved.

In the foregoing, the invention made by the inventor of the present invention has been concretely described based on the embodiments. However, it is needless to say that the present invention is not limited to the foregoing embodiments and various modifications and alterations can be made within the scope of the present invention.

A manufacturing technique of a phase-change memory according to the present invention is applicable to a structure of a phase-change memory which is capable of low-current rewrite and a method of manufacturing the same.

What is claimed is:

1. A phase-change memory comprising:
an insulating film and a plug formed over a semiconductor substrate;
a phase-change film formed over the plug; and
an electrode film formed over the phase-change film,
wherein the phase-change film and the insulating film are in contact with each other in an area formed by projecting an upper surface of the plug to a plane including a lower surface of the electrode film.

2. The phase-change memory according to claim 1,
wherein the electrode film surrounds the entire circumference of the insulating film.

3. The phase-change memory according to claim 1,
wherein the electrode film exists in a part of the area formed by projecting the upper surface of the plug to the plane having the lower surface of the electrode film.

4. A method of manufacturing a phase-change memory comprising the steps of:
forming an insulating film and a plug over a semiconductor substrate;
forming a phase-change film over the plug;
forming an electrode film over the phase-change film;
etching the electrode film in an area formed by projecting an upper surface of the plug to a plane including a lower surface of the electrode film until the phase-change film is exposed; and
forming an insulating film over the electrode film.

5. A phase-change memory comprising:
an interlayer insulating film and a plug formed on one main surface side of a semiconductor substrate;
a phase-change film which can have different specific resistance values according to a phase change formed over surfaces of the interlayer insulating film and the plug; and
an electrode film formed over an upper surface of the phase-change film,
wherein an insulating film exists over the upper surface of the phase-change film in an area formed by projecting a surface of the plug toward the electrode film.

6. The phase-change memory according to claim 5,
wherein the insulating film covers a part of the surface of the plug and extends to the electrode film.

7. A method of manufacturing a phase-change memory comprising the steps of:
forming an interlayer insulating film and a plug on one main surface side of a semiconductor substrate;
forming a phase-change film which can have different specific resistance values according to a phase-change over surfaces of the interlayer insulating film and the plug;
forming an electrode film over an upper surface of the phase-change film;
etching the electrode film in an area formed by projecting a surface of the plug toward the electrode film until the phase-change film is exposed; and
forming an insulating film over an upper surface of the phase-change film.

8. A method of manufacturing a phase-change memory comprising the steps of:
forming an interlayer insulating film and a plug on one main surface side of a semiconductor substrate;
forming a phase-change film which can have different specific resistance values according to a phase-change over surfaces of the interlayer insulating film and the plug;
forming an electrode film over an upper surface of the phase-change film;
etching the electrode film and the phase-change film in an area formed by projecting a surface of the plug toward the electrode film until the surface of the plug is exposed; and
forming an insulating film covering a part of the surface of the plug and extending to the electrode film.

9. A phase-change memory comprising:
an insulating film and a plug formed over a semiconductor substrate;
a phase-change film formed over the plug; and
an electrode film formed over the phase-change film,
wherein a hole is formed in the electrode film in an area formed by projecting an upper surface of the plug to a plane including a lower surface of the electrode film, and the hole part is filled with an insulating film.
